(19) United States
(12) Patent Application Publication
(10) Pub. No.: US 2010/0044786 A1
(43) Pub. Date: Feb. 25, 2010

(54) SEMICONDUCTOR DEVICE

(75) Inventors: HISAO INOMATA, KANAGAWA (JP); YOSHINAO MIURA, KANAGAWA (JP)

Correspondence Address: YOUNG & THOMPSON, 209 Madison Street, Suite 500, Alexandria, VA, 22314, US

(73) Assignee: NEC ELECTRONICS CORPORATION, KANAGAWA (JP)

(21) Appl. No.: 12/542,139

(22) Filed: Aug. 17, 2009

(30) Foreign Application Priority Data
Aug. 19, 2008 (JP) 2008-211025

(51) Int. Cl. H01L 29/78

(52) U.S. Cl. 257/330; 257/E29.257; 257/341

(57) ABSTRACT

A semiconductor device includes: a semiconductor layer of a first conductivity type; a base region of a second conductivity type formed on a surface of the semiconductor layer of the first conductivity type; a plurality of first column regions of the second conductivity type formed in a matrix fashion in the semiconductor layer when seen in a plan view; a trench gate formed in a grid fashion in the semiconductor layer so that each of the first column regions is surrounded by the trench gate when seen in a plan view, the trench gate penetrating through the base region to reach the semiconductor layer of the first conductivity type; and a plurality of second column regions of the second conductivity type selectively formed below each intersection of the grid of the trench gate except line section of the trench gate.

This application is based on Japanese patent application No. 2008-211025, the content of which is incorporated herein by reference.

### BACKGROUND

1. Technical Field

The present invention relates to a semiconductor device having a super-junction structure.

2. Related Art

On-resistance and breakdown voltage that are essential characteristics of a power device are in a trade-off relationship. The on-resistance and the breakdown voltage depend on the resistivity of the semiconductor layer used mainly as a breakdown voltage maintaining layer. When the on resistance is lowered by increasing the added impurity concentration and reducing the resistivity in the semiconductor layer, the breakdown voltage becomes lower. In recent years, a super-junction structure that can greatly improve the trade-off properties and reduce the on-resistance has been suggested. A vertical power MOS field effect transistor (MOSFET) having such a super-junction structure is disclosed by H. Ninomiya, Y. Miura, and K. Kobayashi in “Ultra-low On-resistance 60-100V Superjunction UMOSFETs Fabricated by Multiple Ion-Implantation”, IEEE Proceeding of 2004 International Symposium on Power Semiconductor Devices & ICs, p.p. 177-180, May 24, 2004.

FIG. 7 is a cross sectional view of the conventional vertical power MOSFET having a super-junction structure disclosed in “Ultra-low On-resistance 60-100V Superjunction UMOSFETs Fabricated by Multiple Ion-Implantation”. The vertical power MOSFET includes an N⁺-type silicon substrate 201, an N-type epitaxial layer 202 formed on the surface of the silicon substrate 201, and a P-type base region 203 and an N⁺-type source region 204 formed on the surface of the N-type epitaxial layer 202. The vertical power MOSFET also includes a gate trench 205 that is formed in the N-type epitaxtial layer 202, penetrating through the P-type base region 203 and the N⁺-type source region 204. A gate oxide film 206 and a trench gate 207 made of polysilicon are buried in the gate trench 205. P-type column regions 209 are formed in a vertical direction between the adjacent portions of the trench gates 207 in the N-type epitaxial layer 202. An oxide interlayer 208 is formed on the trench gate 207, and a source electrode is formed on the surface of the oxide interlayer 208. Part of the N⁺-type source region 204 is exposed through the oxide interlayer 208, and the N⁺-type source region 204 and the source electrode 210 are in contact with each other at the exposed portion. A drain electrode 211 is formed on the bottom face of the N⁺--type silicon substrate 201.

In an application of a DC-DC converter circuit such as a small-sized personal computer (PC) or a communication device that requires high-speed switching, it is essential to reduce the parasitic capacitance in reducing the switching loss. To effectively reduce the parasitic capacitance, the density of the cells forming a transistor is lowered, and the total area of the gate oxide film is reduced. When the cell density is lowered, however, the cell size becomes relatively large. As a result, the distance between each two adjacent portions of the trench gate becomes longer, and the distance between each two adjacent P-type column regions formed in the super-junction structure becomes longer. If the distance between each two adjacent P-type column regions becomes longer, a sufficient depletion layer is not formed at the center portion of the N-type epitaxial layer between the column regions, and the breakdown voltage becomes lower.

To solve this problem, Japanese Patent Application Laid-open (JP-A) No. 2006-310621 discloses a structure in which column regions are also provided below the trench gate. By forming column regions below the trench gate and between the portions of the trench gate, the distance between each two adjacent column regions becomes shorter. Accordingly, a uniform depletion layer can be formed, and a higher breakdown voltage can be achieved.

Also, JP-A No. 2007-12977 discloses a structure in which a gate electrode is formed on either an n-column layer or a p-column layer in a super-junction structure.

The present inventor have recognized as follows. When column regions are formed in the entire area below the trench gate according to the technique disclosed in JP-A No. 2006-310621, problems are caused, in which the drain current path is restricted, and the on-resistance becomes higher. Especially, in a case where a trench gate 12 is designed to surround each column region 30 as shown in FIG. 8A, the arrangement of column regions 32 below the trench gate 12 becomes as shown in FIG. 8B, if the column regions 32 are formed in the entire area below the trench gate 12. When the P-type column regions are formed in a continuous lattice-like fashion in the N-type epitaxial layer in this manner, the drain current path is further restricted, and the on-resistance becomes even higher.

### SUMMARY

In one embodiment, there is provided a semiconductor device including: a semiconductor layer of a first conductivity type; a base region of a second conductivity type formed on a surface of the semiconductor layer of the first conductivity type; a plurality of first column regions of the second conductivity type formed in a matrix fashion in the semiconductor layer when seen in a plan view; a trench gate formed in a grid fashion in the semiconductor layer so that each of the first column regions is surrounded by the trench gate when seen in a plan view, the trench gate penetrating through the base region to reach the semiconductor layer of the first conductivity type; and a plurality of second column regions of the second conductivity type selectively formed below each intersection of the grid of the trench gate except line section of the trench gate.

In this structure, the drain current path can be secured, and an increase in on-resistance can be prevented. Also, as the second column regions as well as the first column regions are provided, the distance between each two adjacent columns can be made shorter. Accordingly, a uniform depletion layer can be formed, and a higher breakdown voltage can be achieved. Furthermore, as the second column regions are provided at the four corners of each cell, current concentration at the corners of each cell can be prevented. Accordingly, the resistance to an avalanche to be caused when an inductive load is applied can be greatly improved.

Any combinations of the above described components and any methods and devices to which the present invention described in this specification is applied are also regarded as embodiments of the present invention.

According to the present invention while the drain current path can be secured, the breakdown voltage can be efficiently Improved.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are plan views showing the structure of a MOSFET in an embodiment of the present invention;

FIG. 2 is a cross-sectional view of the MOSFET, taken along the line A-A′ of FIGS. 1A and 1B;

FIG. 3 is a cross-sectional view of the MOSFET, taken along the line B-B′ of FIGS. 1A and 1B;

FIG. 4 is a cross-sectional view of another example of the MOSFET of this embodiment;

FIG. 5 is a cross-sectional view of yet another example of the MOSFET of this embodiment;

FIGS. 6A and 6A are plan views showing still another example of the MOSFET of this embodiment;

FIG. 7 illustrates problems with a conventional semiconductor device;

FIGS. 8A and 8B illustrate problems with another conventional semiconductor device; and

FIG. 9 shows the relationship between the on-resistance per unit area and the breakdown voltage in the MOSFET of this embodiment, and the relationship between the on-resistance per unit area and the breakdown voltage in a MOSFET having P-type column regions formed in the entire area below the trench gate.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The following is a description of an embodiment of the present invention, with reference to the accompanying drawings. In the drawings, like components are denoted by like reference numerals, and explanation of them will not be repeated.

The semiconductor device of this embodiment to be described below is a MOS field effect transistor (MOSFET) having a super-junction structure. The semiconductor device may be any other vertical power device such as an insulated gate bipolar transistor (IGBT) having a super-junction structure.

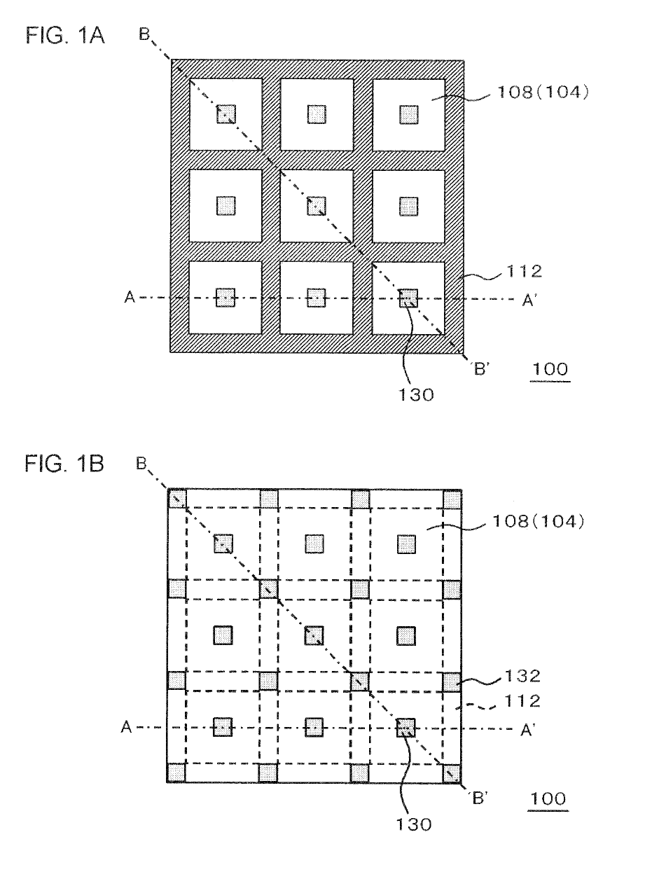

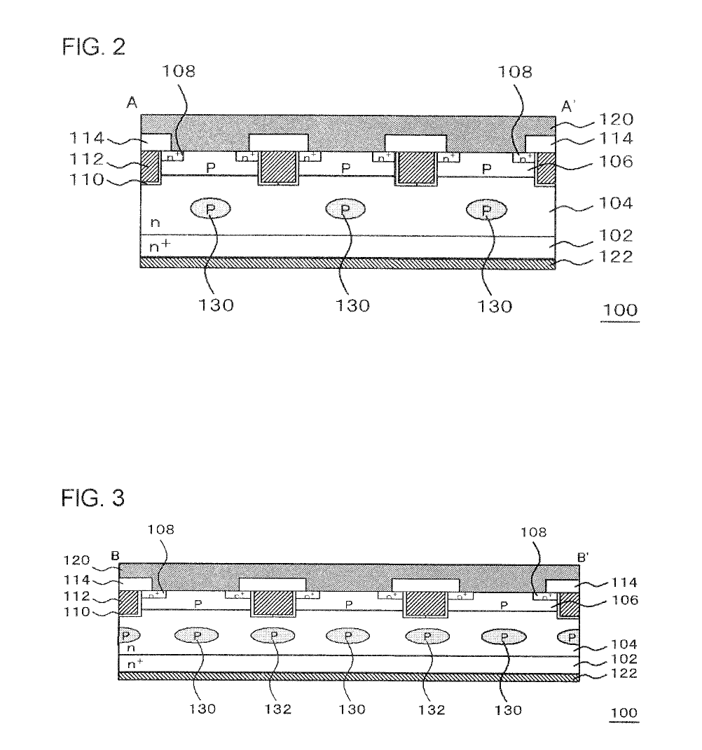

FIGS. 1A and 1B are plan views showing the structure of the MOSFET in this embodiment. To facilitate understanding of this embodiment, FIG. 1A shows a trench gate 112 and first column regions 130. FIG. 1B shows the first column regions 130 and second column regions 132. In FIG. 1B, each area in which the trench gate 112 is formed is shaded. FIG. 2 is a cross-sectional view of the MOSFET, taken along the line A-A′ of FIGS. 1A and 1B. FIG. 3 is a cross-sectional view of the MOSFET, taken along the line B-B′ of FIGS. 1A and 1B.

In this embodiment, the MOSFET 100 includes: a silicon substrate (substrate) 102 of an N⁺-type (first conductivity type); an epitaxial layer (semiconductor layer) 104 of an N-type (first conductivity type) formed on the principal surface side of the silicon substrate 102; a base region 106 of a P-type (second conductivity type) formed on the surface of the epitaxial layer 104; the first column regions 130 of the P-type (second conductivity type) formed in a matrix fashion in the epitaxial layer 104 when seen in a plan view; and the trench gate 112 formed on the principal surface of the epitaxial layer 104. The trench gate 112 surrounds each of the first column regions 130 when seen in a plan view, and penetrates through the base region 106 to reach the epitaxial layer 104 The trench gate 112 is formed in a grid fashion or in a mesh fashion in the epitaxial layer 104 so that each of the first column regions 130 is surrounded by the trench gate 112 when seen in a plan view. Here, each of the first column regions 130 may have a square shape with curve corners when seen in a plan view and the trench gate 112 surrounds the four sides of each of the first column regions 130. The MOSFET 100 further includes the second column regions 132 of the P-type (second conductivity type) selectively formed below each intersection of the grid of the trench gate 112 except line section of the trench gate 112. It means that the second column regions 132 are only formed at the four corners of each of the first column regions 130, and are located below the trench gate 112.

The MOSFET 100 further includes: a source region 108 of the N-type selectively formed on the surface of the epitaxial layer 104; an oxide interlayer 114 formed on the trench gate 112; and a source electrode 120 that is formed on the oxide interlayer 114, and is in contact with the base region 106 and the source region 108.

The trench gate 112 is formed in a gate trench that penetrates through the N⁺-type source region 108 and the P-type base region 106, and is located in-the epitaxial layer 104. The MOSFET 100 further includes a gate oxide film 110 formed in the gate trench, and the trench gate 112 is formed on the gate oxide film 110. The trench gate 112 may be made of polysilicon, for example. The source region 108 is formed on either side of each portion of the trench gate 112, and is formed along the trench gate 112. The source electrode 120 is insulated from the trench gate 112 by the oxide interlayer 114. The MOSFET 100 also includes a drain electrode 122 formed on the bottom face of the silicon substrate 102.

In this embodiment, the first column regions 130 are orthogonally arranged in a first direction (the lateral direction in FIGS. 1A and 1B) and a second direction (the vertical direction in FIGS. 1A and 1B) that is perpendicular to the first direction, when seen in a plan view. The trench gate 112 is formed in a lattice-like fashion in the first direction and the second direction, when seen in a plan view. In this embodiment, the trench gate 112 has portions extending in the first direction and portions extending in the second direction, and each portion extending in the first direction is perpendicular to each portion extending in the second direction. The second column regions 132 are formed below the respective cross-points between the portions of the trench gate 112 extending in the first direction and the portions of the trench gate 112 extending in the second direction. In the first column regions 130, the second column regions 132, and the epitaxial layer 104, the impurity concentrations are set in such a manner that the total depletion charge amount in the first column regions 130 and the second column regions 132 is substantially the same as the depletion charge amount in the epitaxial layer 104.

In this embodiment, the second column regions 132 are formed at such a depth as not to be in contact with the bottom of the trench gate 112, as shown in FIGS. 2 and 3. With this arrangement, the path for the on-current flowing along the trench gate 112 can be secured. Accordingly, an increase in on-resistance can be prevented. Also, the first column regions 130 are formed at the same depth as the second column regions 132. Accordingly, the first column regions 130 are not in contact with the bottom of the base region 106 located at a shallower position than the bottom of the trench gate 112, and are formed at such a depth as to keep a distance from the base region 106.

Next, the procedures for manufacturing the MOSFET 100 of this embodiment are described.

First, the n-type epitaxial layer 104 having lower impurity concentration than the silicon substrate 102 is grown on the surface of the N⁺-type silicon substrate 102. Boron (B) ions are then implanted with an energy of approximately 1.5 MeV by a photolithography technique, so as to form the first column regions 130 and the second column regions 132 at the same time.

In this embodiment, the epitaxial layer 104 may have a specific resistance of 4.4 mΩm and a thickness of 4 μm. Each cell surrounded by the trench gate 112 may have a square shape of 4 μm in each side, for example. In this structure, boron (B) ions are implanted with a dose amount of 9.0e12 atm/cm² into the center of each cell and a column pattern of squares that are located at the four corners of the cell and are 1 μm in each side. In this manner, the first column regions 130 and the second column regions 132 are formed. Since the first column regions 130 and the second column regions 132 are formed in the same ion implanting procedure in this embodiment, they are formed at the same depth. Also, the first column regions 130 and the second column regions 132 have the same concentration profile.

A layered film for forming the gate trench is formed on the surface of the epitaxial layer 104. After a silicon oxide film (50 nm in film thickness, for example) is formed on the surface of the epitaxial layer 104 by thermal oxidation, a silicon nitride film (Si₃N₄, 20 nm in film thickness, for example) and a silicon oxide film (200 nm in film thickness, for example) are deposited by the chemical vapor deposition (CVD) method, so as to form the layered film. Patterning is then performed on the layered film by a photolithography technique. With the layered film serving as a mask, silicon etching is performed on the epitaxial layer 104, so as to form the gate trench.

After the oxide film of the outermost surface of the layered film is removed by etching, the opening corners and the bottom corners of the gate trench are rounded by high-temperature oxidation After that, the nitride film of the layered film and the oxide film formed through the rounding process in the gate trench are removed by etching. The gate oxide film 110 (50 nm in film thickness, for example) is further formed through thermal oxidation on the surface of the N-type epitaxial layer 104 and inside the gate trench.

Polysilicon is then deposited in the gate trench by CVD, so as to form the trench gate 112. Etchback is then performed on the polysilicon, so that the polysilicon remains only inside the gate trench.

Boron or boron fluoride (BF₂) ion implantation and a heat treatment in an oxygen atmosphere or a nitrogen atmosphere are performed, so as to form the P-type base region 106 at a shallower depth than the gate trench. By a photolithography technique, As ions are then implanted into the surface of the P-type base region 106, and a heat treatment in a nitrogen atmosphere is performed, so as to form the N⁺-type source region 108. After the oxide interlayer 114 of 1μm in thickness is deposited by CVD, etching is performed on the oxide interlayer 114 by a photolithography technique, so as to expose the N⁺-type source region 108. In this manner, contact regions are formed.

AlSi (aluminum silicon) is then deposited by sputtering, so as to form the source electrode 120. A cover member such as an oxide film or a nitride film is then deposited as a surface protection film, and photolithographic patterning and etching are performed so as to form bonding regions and the likes. Lastly, the bottom face of the silicon substrate 102 is polished off by a desired thickness, and several kinds of metals are vapor-deposited on the bottom face, so as to form the drain electrode 122. Through those procedures, the MOSFET 100 having the structure illustrated in FIGS. 1A through 3 is obtained.

Next, an operation of the MOSFET 100 in this embodiment is described.

When a voltage equal to or higher than a threshold voltage Vt is applied to a gate electrode (not shown) connected to the trench gate 112 in the MOSFET 100, the P-type base region 106 in contact with the sidewalls of the gate trench is reversed to become a channel, and a drain current flows as a result of the application of a drain voltage. In an ON state, the current path is formed with the source electrode 120, the N⁺-type source region 108, the N-type epitaxial layer 104, the N⁺-type silicon substrate 102, and the drain electrode 122.

In an OFF state where a voltage is not applied to the gate electrode, a high voltage can he applied between the source and drain, and a depletion layer is formed at the PN junctions among the N-type epitaxial layer 104, P-type base region 106, the first column regions 130, and the second column regions 132. As the voltage between source and drain becomes higher, the depletion layer expands in the transverse direction, and at last, the depletion layer has a uniform thickness in the entire N-type epitaxial layer 104. When an even higher voltage is applied between the source and drain, and the breakdown voltage is exceeded, a breakdown is caused, and an avalanche current flows between the source and drain.

In the MOSFET 100 of this embodiment, the P-type first column regions 130 are formed between the respective portions of the trench gate 112, and the P-type second column regions 132 are formed below the trench gate 112 at the four corners of each of the first column regions 130. In this structure, sufficient depletion can be performed in the entire epitaxial layer 104, and the breakdown voltage can be made higher.

As in the MOSFET 100 of this embodiment, in a layout having unit cells surrounded by the trench gate 112 and regularly arranged in a lattice-like fashion, the distance between each two adjacent first column regions 130 becomes longest in the diagonal direction shown in FIGS. 1A and 1B. Since the second column regions 132 are formed in the direction in which the distance between each two adjacent first column regions 130 becomes longest in this embodiment, the breakdown voltage can be efficiently increased, and the drain current path can be more effectively secured than in a case where column regions are formed in the entire area below the trench gate 112.

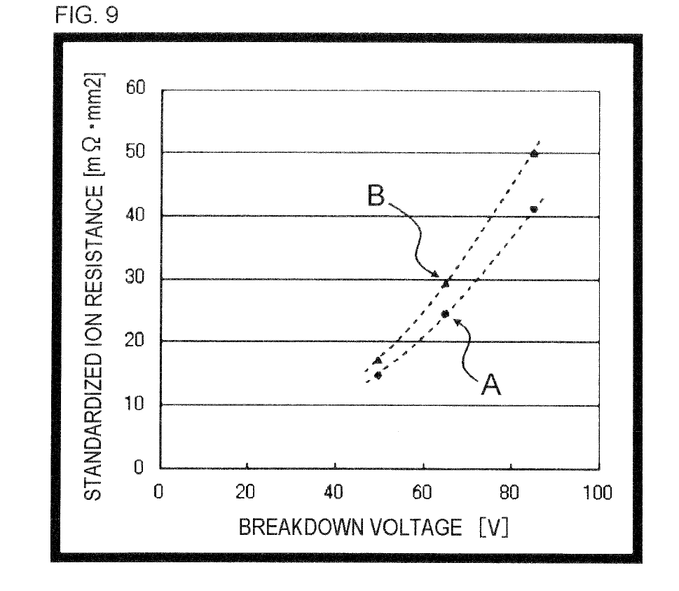

FIG. 9 shows the relationship between the on-resistance per unit area and the breakdown voltage in the MOSFET 100 of this embodiment (denoted by A in FIG. 9), and the relationship between the on-resistance per unit area and the breakdown voltage in a MOSFET (denoted by B in FIG. 9) having P-type column regions formed in the entire area below the trench gate 112. In either case, each cell is 4 μm² in size. In the MOSFET 100 of this embodiment, the cross-section area of each P-type column region is reduced to approximately ⅛ of the cross-section area of each P-type column region in the MOSFET having the P-type column regions formed in the entire area below the trench gate 112. Accordingly, lower on-resistance can be achieved in the MOSFET 100.

Also, as the second column regions 132 are formed below the respective cross-points of the gate trench, the resistance to an avalanche observed when an inductive load is applied can be greatly improved. This is probably because damage to the chips by the bipolar action can be effectively prevented by avoiding current concentration at the corners of each cell. Accordingly, in the MOSFET 100 of this embodiment, lower on-resistance can be achieved with a high breakdown voltage, and even higher resistance to the inductive load can be provided.

Although an embodiment of the present invention has been described with reference to the drawings, the embodiment is merely an example, and various other structures may be employed.

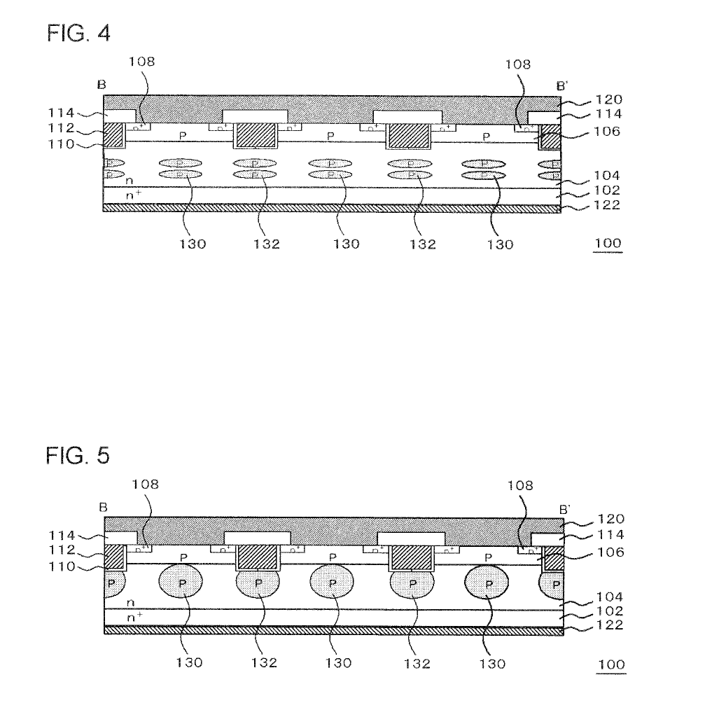

FIG. 4 is a cross-sectional view showing another example of the MOSFET 100 of the above described embodiment. The first column regions 130 and the second column regions 132 may be formed in two or more areas partitioned in the depth directions. Such a structure can be formed by performing ion implantation two or more times, with the ion implanting depth being varied. With this arrangement, the impurity concentration distribution of the first column regions 130 and the second column regions 132 can be controlled in the vertical direction. Accordingly, a higher degree of freedom is allowed in electric field design, and a higher breakdown voltage can be achieved.

FIG. 5 is a cross-sectional view showing yet another example of the MOSFET 100 of the above described embodiment. The second column regions 132 may be formed at such a depth as to be in contact with the bottom of the trench gate 112. The first column regions 130 may be formed in contact with the bottom of the base region 106, and may be integrally formed with the base region 106. With this structure, the same effects as those of the MOSFET 100 of the above described embodiment can be achieved. Also, electric field concentration at the bottom of the trench gate 112 can be prevented. Thus, it is considered that the resistance to an avalanche at the time of application of the inductive load can be increased.

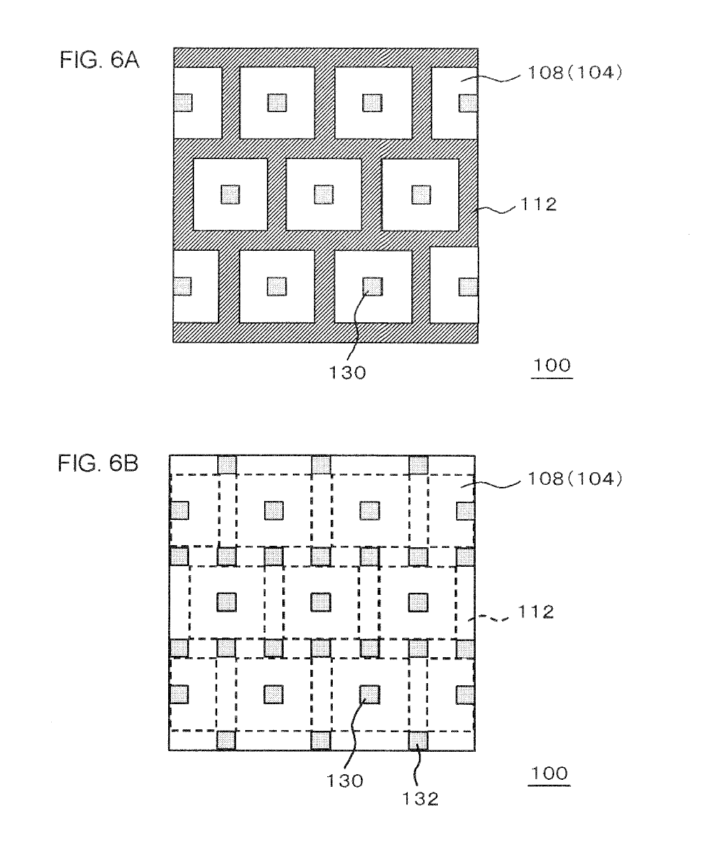

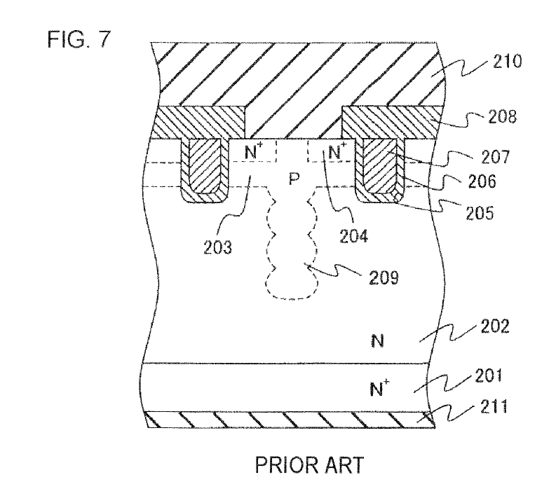

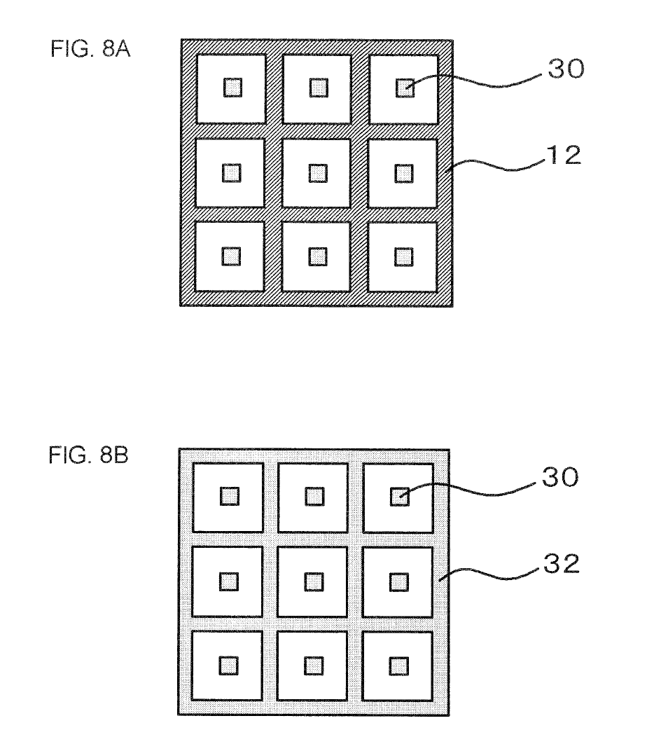

FIGS. 6A and 6B are plan views showing still another example of the MOSFET 100 of this embodiment. To facilitate understanding of this example, FIG. 6A shows the trench gate 112 and the first column regions 130. FIG. 6B shows the first column regions 130 and the second column regions 132. In FIG. 6B, the portions at which the trench gate 112 is formed are shaded.

In the plan views, the first column regions 130 are arranged in the first direction (the lateral direction in FIGS. 6A and 6B) and are also arranged in a third direction diagonal to the first direction when seen in a plan view. Accordingly, the first column regions 130 are arranged in a diagonal lattice-like fashion. In the plan view, the trench gate 112 is designed to surround the first column regions 130 in the first direction and the second direction (the vertical direction in FIGS. 6A and 6B) perpendicular to the first direction. In this structure, sufficient depletion can also be performed in the entire epitaxial layer 104, and the breakdown voltage can be made higher. Also, since the second column regions 132 are arranged at the four corners of each cell, current concentration at the corners of each cell can be prevented, and the resistance to an avalanche caused at the time of application of the inductive load can be greatly improved. Further, a greater current path can be secured than in a case where the column regions are formed in the entire area below the trench gate 112. Thus, the on-resistance is lowered, and a higher breakdown voltage can be achieved.

It is apparent that the present invention is not limited to the above embodiment, and may be modified and changed without departing from the scope and spirit of the invention.

What is claimed is:

1. A semiconductor device comprising:
a semiconductor layer of a first conductivity type;
a base region of a second conductivity type formed on a surface of said semiconductor layer of said first conductivity type;
a plurality of first column regions of said second conductivity type formed in a matrix fashion in said semiconductor layer when seen in a plan view;
a trench gate formed in a grid fashion in said semiconductor layer so that each of said first column regions is surrounded by said trench gate when seen in a plan view, said trench gate penetrating through said base region to reach said semiconductor layer of said first conductivity type; and
a plurality of second column regions of said second conductivity type selectively formed below each intersection of said grid of said trench gate except line section of said trench gate.

2. The semiconductor device as claimed in claim 1, wherein:
said first column regions are orthogonally arranged in a first direction and a second direction that is perpendicular to said first direction, when seen in a plan view; and
said trench gate is formed in a lattice-like fashion in said first direction and said second direction, when seen in a plan view.

3. The semiconductor device as claimed in claim 1, wherein:
said first column regions are arranged in a diagonal lattice-like fashion along a first direction and a third direction that is diagonal to said first direction, when seen in a plan view; and
said trench gate surrounds said first column regions in said first direction and a second direction that is perpendicular to said first direction, when seen in a plan view.

4. The semiconductor device as claimed in claim 1, wherein said first column regions and said second column regions are formed at the same depth.

5. The semiconductor device as claimed in claim 1, wherein said second column regions are formed at such a depth as not to be in contact with a bottom of said trench gate.

6. The semiconductor device as claimed in claim 1, wherein said second column regions are formed at such a depth as to be in contact with a bottom of said trench gate.

7. The semiconductor device as claimed in claim 1, wherein said first column regions are formed at such a depth as not to be in contact with a bottom of said base region and to be at a distance from said base region.

8. The semiconductor device as claimed in claim 1, wherein said first column regions are formed at such a depth as to be in contact with a bottom of said base region and to be integrally formed with said base region.

9. The semiconductor device as claimed in claim 1, wherein said first column regions and said second column regions are formed in a plurality of areas partitioned in a depth direction.
